(19) United States
(12) Patent Application Publication
(10) Pub. No.: US 2025/0301744 A1
(43) Pub. Date: Sep. 25, 2025

(54) SEMICONDUCTOR DEVICE HAVING NANOSHEET TRANSISTOR AND METHODS OF FABRICATION THEREOF

(71) Applicant: TAIWAN SEMICONDUCTOR MANUFACTURING COMPANY, LTD., Hsinchu (TW)

(72) Inventors: Chih Li CHANG, Hsinchu (TW); Shu-Uei JANG, Hsinchu City (TW); Yi Tzu HUANG, Hsinchu County (TW); Shu-Yuan KU, Hsinchu County (TW)

(21) Appl. No.: 18/611,859

(22) Filed: Mar. 21, 2024

(51) Int. Cl. H01L 29/66; H01L 21/3065; H01L 29/06; H01L 29/775; H01L 29/786

(52) U.S. Cl. CPC H10D 64/018; H01L 21/3065; H10D 30/014; H10D 30/031; H10D 30/43; H10D 30/6757; H10D 62/116

(57) ABSTRACT

Various embodiments of the present disclosure provide a method for forming a semiconductor device structure. The method includes forming a sacrificial gate structure over a portion of a fin structure comprising a plurality of first semiconductor layers and a plurality of second semiconductor layers alternatingly stacked. The method also includes removing a portion of the fin structure not covered by the sacrificial gate structure, subjecting exposed surfaces of each first and second semiconductor layers to at least one radical species, removing an edge portion of the second semiconductor layers to form a cavity between two adjacent first semiconductor layers, and forming a dielectric spacer in the cavity.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down presents new challenge. For example, transistors using nanostructure channels have been proposed to improve carrier mobility and drive current in a device. An inner spacer is often disposed between metal gate and source/drain (S/D) structure to protect the S/D structure from damage that may occur during the subsequent gate replacement process. Although the formation of the inner spacer has been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure in accordance with some embodiments.

FIGS. 7A-8A and 11A-18A are cross-sectional side views of various stages of manufacturing the semiconductor device structure taken along cross-section A-A of FIG. 6, in accordance with some embodiments.

FIGS. 7B-8B and 11B-18B are cross-sectional side views of various stages of manufacturing the semiconductor device structure taken along cross-section B-B of FIG. 6, in accordance with some embodiments.

FIGS. 7C-8C and 11C-18C are cross-sectional side views of various stages of manufacturing the semiconductor device structure taken along cross-section C-C of FIG. 6, in accordance with some embodiments.

FIGS. 7D-8D and 11D-18D are top views of various stages of manufacturing the semiconductor device structure taken along cross-section D-D of FIG. 6, in accordance with some embodiments.

FIG. 7E illustrates a top view of the semiconductor device structure taken along cross-section E-E of FIG. 6, in accordance with some embodiments.

FIG. 8E illustrates a top view of the semiconductor device structure taken along cross-section E-E of FIG. 6, in accordance with some embodiments.

FIG. 9 illustrates a portion of the semiconductor device structure of FIG. 8A, in accordance with some embodiments.

FIG. 10 illustrates a portion of the semiconductor device structure of FIG. 8D after edge portions of each second semiconductor layer of the stack of semiconductor layers are removed, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

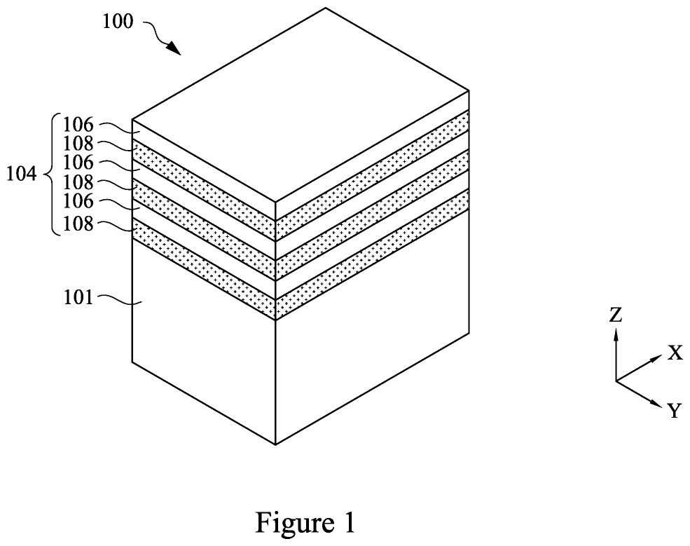

FIGS. 1 to 18D show non-limiting processes for manufacturing a semiconductor device structure 100 according to embodiments of the present disclosure. It is understood that additional operations can be provided before, during, and after processes shown by FIGS. 1 to 18D, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100 in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 101 is made of silicon. The substrate 101 may be doped or un-doped. The substrate 101 may be a bulk semiconductor substrate, such as a bulk silicon substrate that is a wafer, a silicon-on-insulator (SOI) substrate, a multi-layered or gradient substrate, or the like.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108 vertically stacked over the substrate 101. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

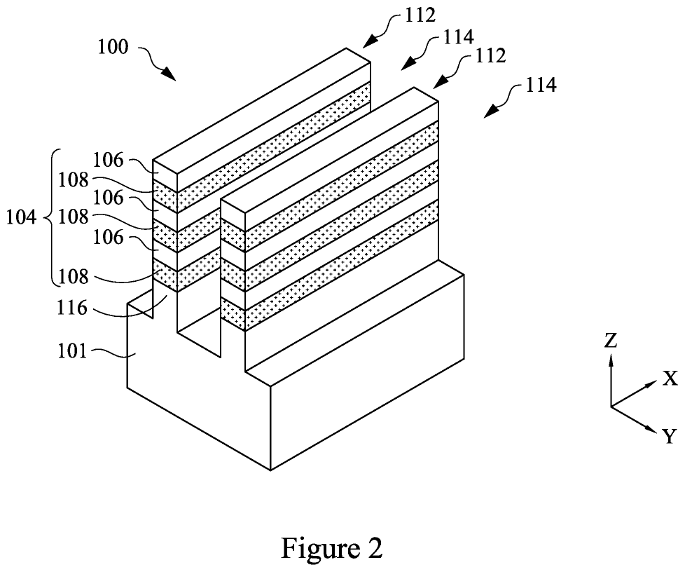

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

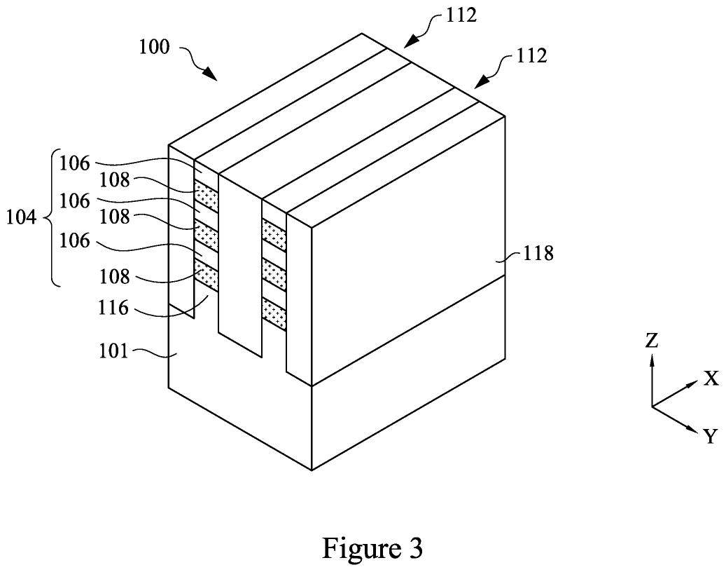

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

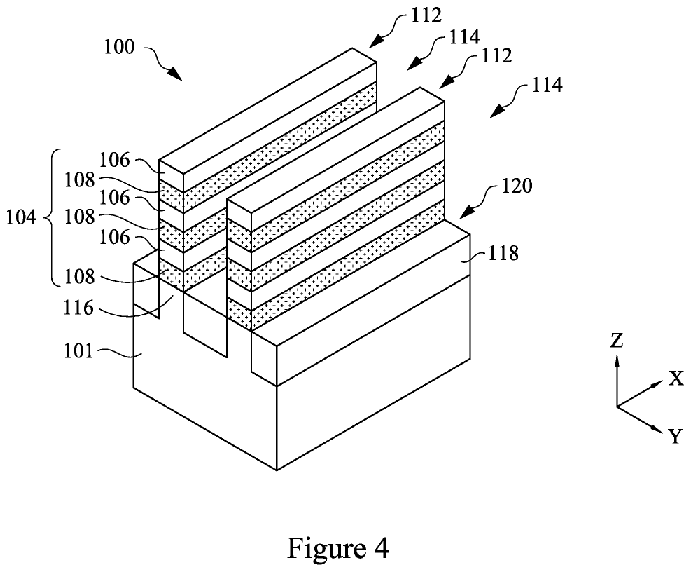

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or at a below a surface of the second semiconductor layers 108 in contact with the well portion 116 formed from the substrate 101.

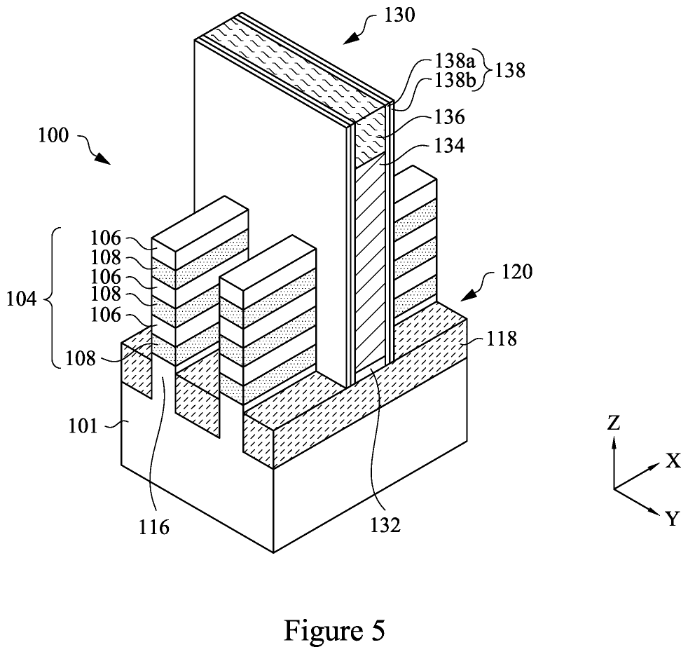

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as silicon oxide (SiOₓ) or a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof. In some embodiments, the gate spacer 138 may be a dual-layer including a first dielectric layer 138a (e.g., SiO₂) and a second dielectric layer 138b (e.g., SiN).

The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. It should be understood that the source region and the drain region can be interchangeably used since the epitaxial features to be formed in these regions are substantially the same. Source/drain region(s) may refer to a source or a drain, individually or collectively dependent upon the context.

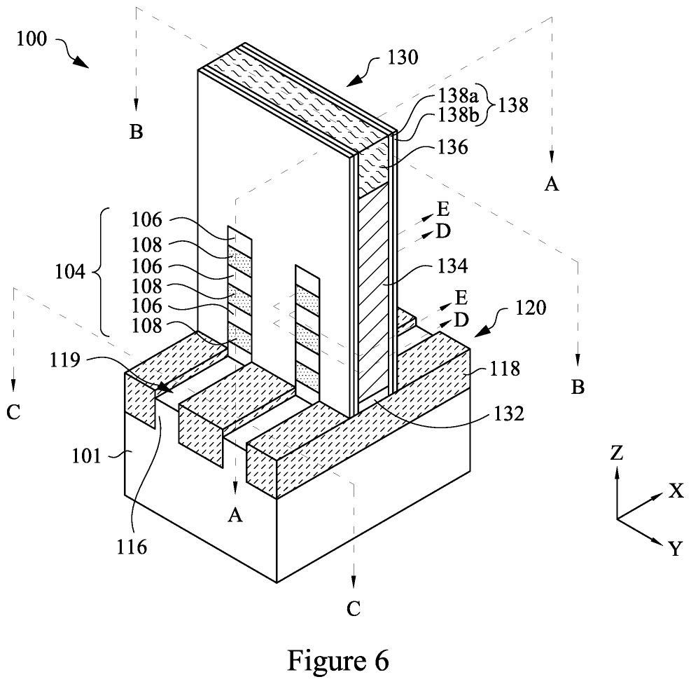

In FIG. 6, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

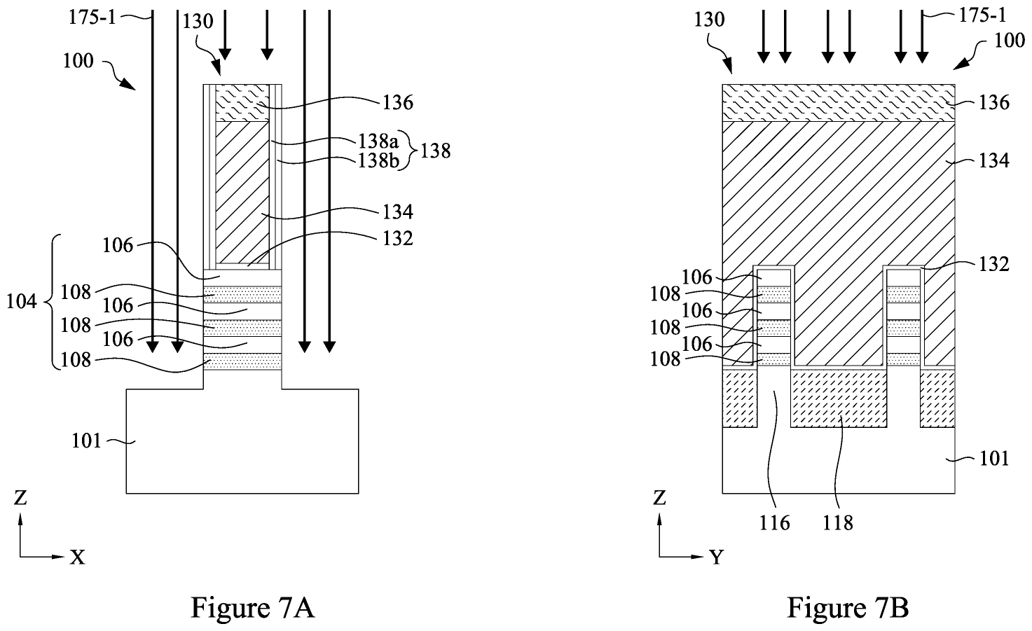

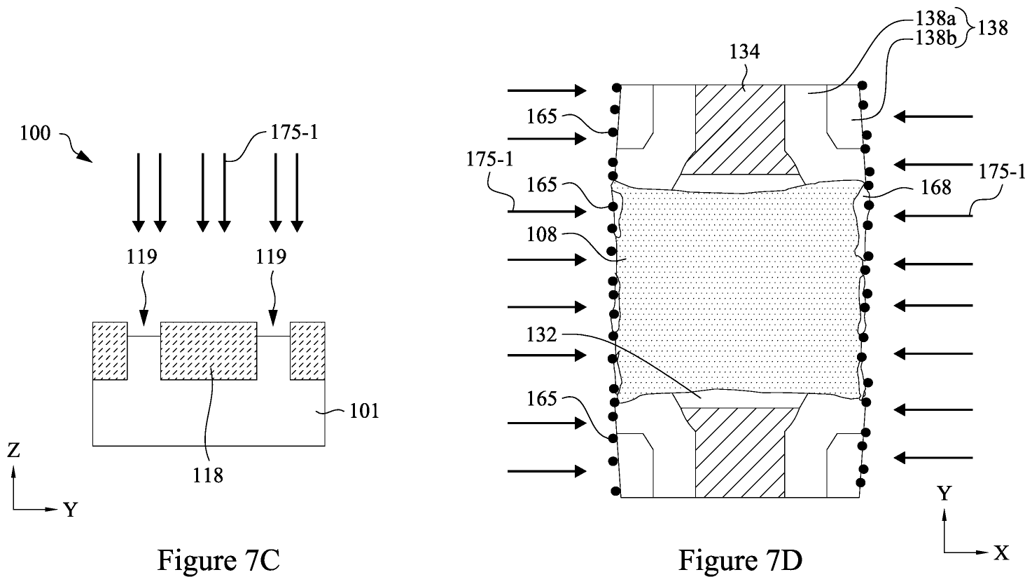

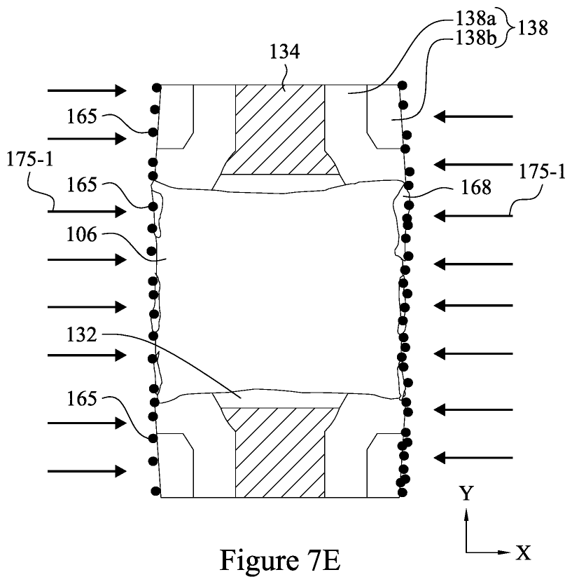

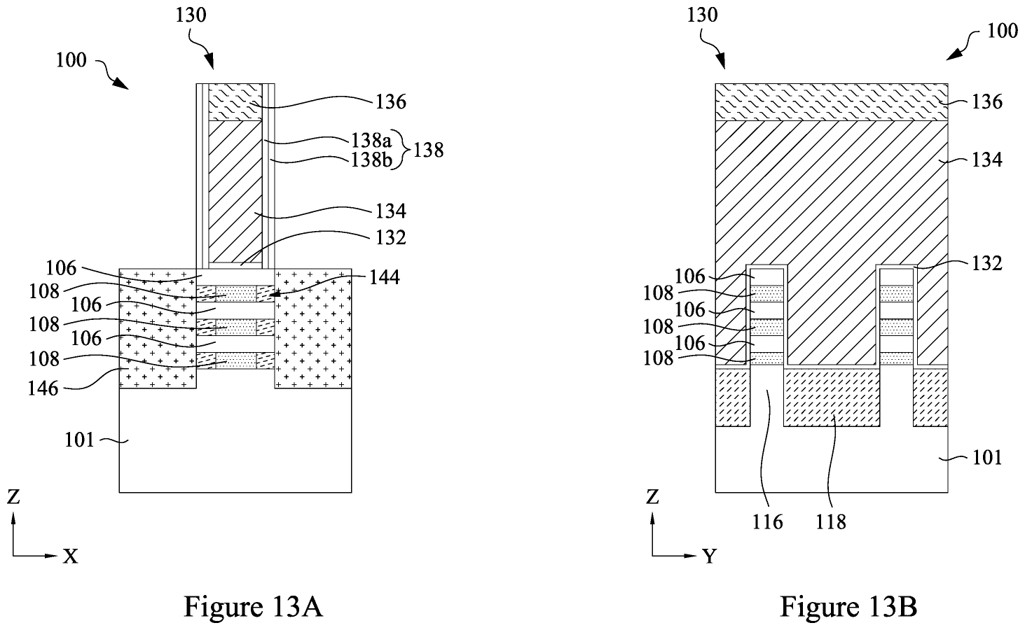

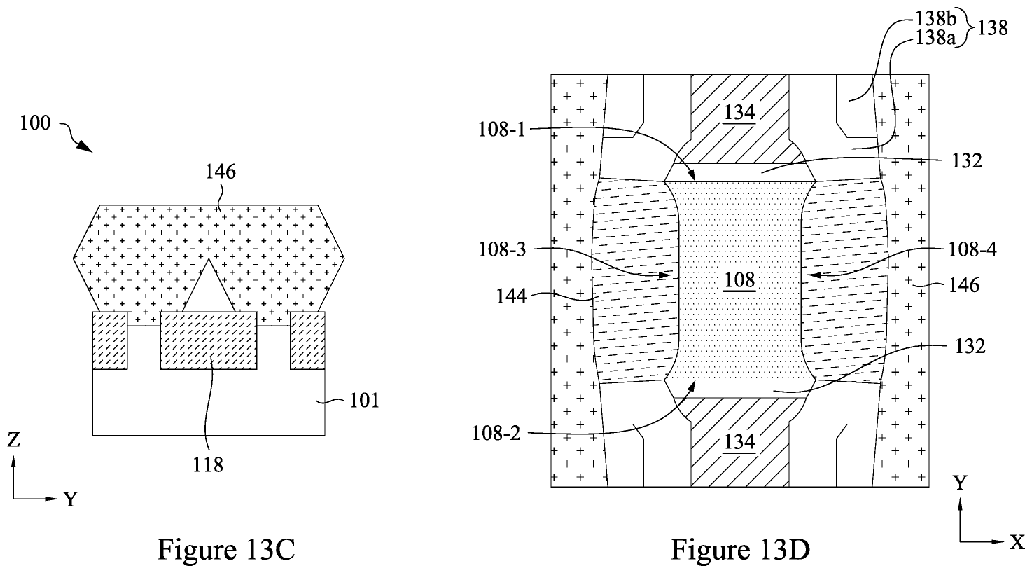

FIGS. 7A-8A and 11A-18A are cross-sectional side views of various stages of manufacturing the semiconductor device structure 100 taken along cross-section A-A of FIG. 6, in accordance with some embodiments. FIGS. 7B-8B and 11B-18B are cross-sectional side views of various stages of manufacturing the semiconductor device structure 100 taken along cross-section B-B of FIG. 6, in accordance with some embodiments. FIGS. 7C-8C and 11C-18C are cross-sectional side views of various stages of manufacturing the semiconductor device structure 100 taken along cross-section C-C of FIG. 6, in accordance with some embodiments. FIGS. 7D-8D and 11D-18D are top views of various stages of manufacturing the semiconductor device structure 100 taken along cross-section D-D of FIG. 6, in accordance with some embodiments. Cross-section A-A are in a plane of the fin structure 112 (FIG. 4) along the X direction. Cross-section B-B is in a plane perpendicular to cross-section A-A and is in the sacrificial gate structure 130 along the Y direction. Cross-section C-C is in a plane perpendicular to cross-section A-A and is in the S/D features 146 (FIG. 13A) along the Y-direction. Cross-section D-D is in a plane of the second semiconductor layer 108 along the X direction.

In FIGS. 7A-7D, the semiconductor device structure 100 is subjected to a pre-treatment process 175-1. FIG. 7E illustrates a top view of the semiconductor device structure 100 taken along cross-section E-E of FIG. 6, in accordance with some embodiments. The pre-treatment process 175-1 is operated to remove residues 168 generated during the etch process of the portions of the fin structures 112 (FIG. 6). The residues 168 may be deposited on the exposed surfaces of the gate spacer 138 and/or the stack of semiconductor layers 104. Possible residues 168 may include post-etch residues, which can be by-products of a chemical reaction between the etchant and the material of exposed surfaces of the gate spacer 138 (e.g., silicon oxycarbide (SiOC)), the stack of semiconductor layers 104 (e.g., silicon oxide (SiOₓ, x=1˜3), germanium oxide (GeOₓ, x=1˜3), etc.), and/or those native oxides formed on exposed surfaces of the stack of semiconductor layers 104 as a result of exposure to air after the etch process. If no pre-treatment process were performed, the exposed surfaces of the second semiconductor layers 108 may have noticeable critical dimension (CD) variation and irregular surface roughness after the selective etching process. Large CD variation and worse roughness of the second semiconductor layers 108 will lead to the thickness of the subsequent inner spacer to suffer, which may result in unwanted damage to the epitaxial source/drain features 146 due to the broken inner spacer. The uniformity of surface roughness has become one of the critical factors affecting device performance. The pre-treatment process 175-1 removes the surface impurities (e.g., O/C/N signals) so as to control the CD variation and surface roughness of the second semiconductor layers 108, and improve EPI damage window. As a result, the device electrical performance is improved.

The pre-treatment process 175-1 may include a surface treatment process and a surface cleaning process. The surface treatment process may be a process using reactive etch species generated in-situ in a reaction chamber where the semiconductor device structure 100 is disposed, or in an upstream of a reaction chamber (e.g., from a remote plasma generator). The reactive species are then filtered so that only radical species are used to treat the exposed surfaces of the stack of semiconductor layers 104. The reaction chamber may be a plasma-based process chamber, such as a decoupled plasma chamber, a remote plasma chamber, or a combination thereof. The plasma may be formed by a capacitively coupled plasma (CCP) source or an inductively coupled plasma (ICP) source driven by an RF power generator. In some embodiments, the pre-treatment process 175-1 is a radical surface treatment (RST) using neutral radical species (i.e., a plasma-free process). In some embodiments, the pre-treatment process 175-1 is a plasma surface treatment using plasma species. Exemplary reactive species may include hydrogen plasma or neutral radical species of hydrogen, such as hydrogen radicals (or atomic radicals of hydrogen); nitrogen plasma or neutral radical species of nitrogen, such as nitrogen radicals (or atomic radicals of nitrogen), or a combination thereof. Hydrogen plasma or neutral radical species of hydrogen may be formed from any suitable hydrogen-containing gas, such as hydrogen gas (H₂). Nitrogen plasma or neutral radical species of nitrogen may be formed from any suitable nitrogen-containing gas, such as nitrogen gas (N₂), ammonia (NH₃), nitrous oxide (N₂O), or the like.

In some embodiments, the pre-treatment process 175-1 utilizes neutral radical species generated in a remote plasma generator, and the neutral radical species, such as hydrogen radicals (H*) and nitrogen radicals (N*), are introduced into the downstream reaction chamber at a ratio (N*:H*) of about 6:1 to about 25:1, for example about 16:1. In cases where by-products contain carbon (e.g., SiOC from the gate spacers 138), the hydrogen radicals and the nitrogen radicals of the pre-treatment process 175-1 may react with SiOC to form silicon oxynitride (SiON), silicon hydroxide (SiOH), methane (CH₄), and hydrogen cyanide (HCN), in which CH₄ and HCN can be easily removed from the reaction chamber. In some embodiments, the carbon content on the exposed surfaces of the stack of semiconductor layers 104 is reduced after the surface treatment process. Thereafter, a surface cleaning process using hydrofluoric acid (HF) and/or diluted HF is performed to convert SiON and SiOH into silicon tetrafluoride (SiF₄), water (H₂O), and ammonia (NH₃), which can be easily removed from the reaction chamber. As a result, the residues generated during the etch process of the portions of the fin structures 112 are removed.

While hydrofluoric acid is discussed, the surface cleaning process may be any suitable wet cleaning process. For example, a wet cleaning process using NH₄OH, HF or diluted HF, deionized (DI) water, tetramethylammonium hydroxide (TMAH), other suitable solution, or a combination thereof, may be used. In some embodiments, the surface cleaning process is a standard clean-2 (SC2) followed by a standard clean-1 (SC1), where the SC2 is a mixture of DI water, hydrochloric (HCl) acid, and hydrogen peroxide (H₂O₂), and the SC1 is a mixture of D1 water, NH₄OH, and H₂O₂. In some embodiments, an isopropyl alcohol (IPA) may be used after the SC1. Other suitable wet etch process, such as an APM process, which includes at least water (H₂O), ammonium hydroxide (NH₄OH), and hydrogen peroxide (H₂O₂), a HPM process, which includes at least H₂O, H₂O₂, and hydrogen chloride (HCl), a SPM process (also known as piranha clean), which includes at least H₂O₂ and sulfuric acid (H₂SO₄), or any combination thereof, may also be used.

In cases where ICP source is used, the pre-treatment process 175-1 may be performed in a remote plasma generator. In such cases, the plasma source power may use a continuous wave RF power generator or a pulsed RF power generator operating on a predetermined duty cycle. The source power ionizes the nitrogen-containing gases supplied to the remote plasma generator. The generated nitrogen ions may be filtered to generate neutral radical species (e.g., hydrogen and nitrogen radicals) prior to supplying to the reaction chamber in which the semiconductor device structure 100 is disposed. In one exemplary embodiment, the decoupled plasma process is formed by the ICP source driven by the RF power generator using a tunable frequency ranging from about 2 MHz to about 13.56 MHz, and the chamber is operated at a pressure in a range of about 0.5 Torr to about 8 Torr and a temperature of about 300 degrees Celsius to about 600 degrees Celsius for a process time of about 3 seconds to about 50 seconds. The flow of the processing gas (e.g., hydrogen-containing and nitrogen-containing gas) may be separately provided at about 200 sccm to about 5000 sccm. The RF power generator is operated to provide power between about 50 watts to about 1000 watts, and the output of the RF power generator is controlled by a pulse signal having a duty cycle in a range of about 20% to about 80%.

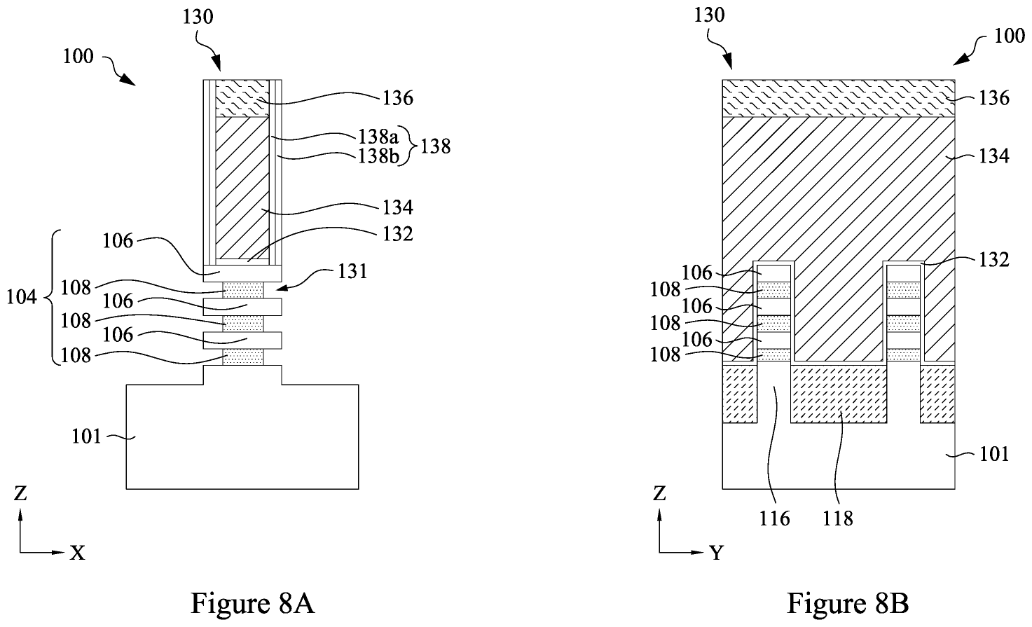

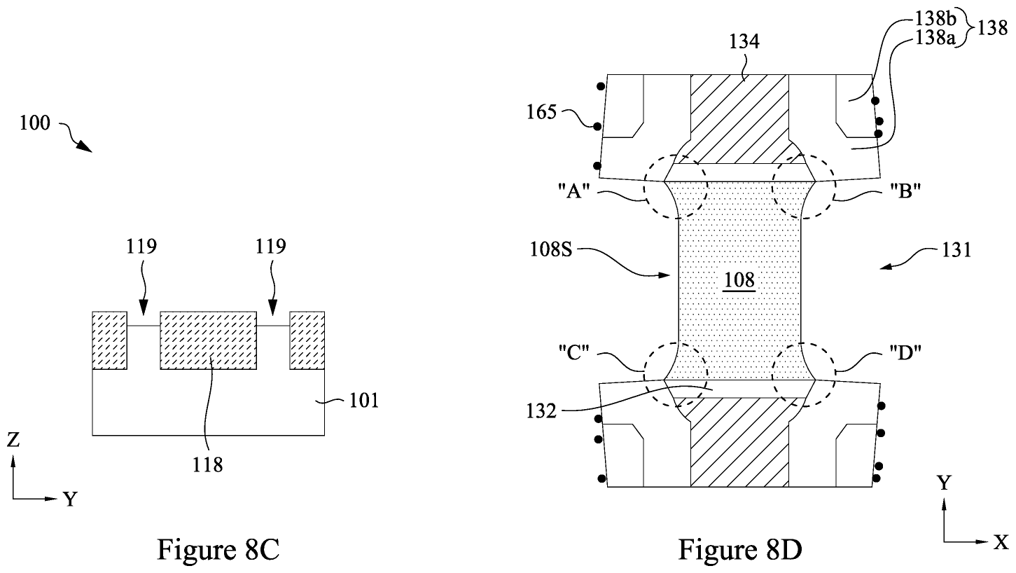

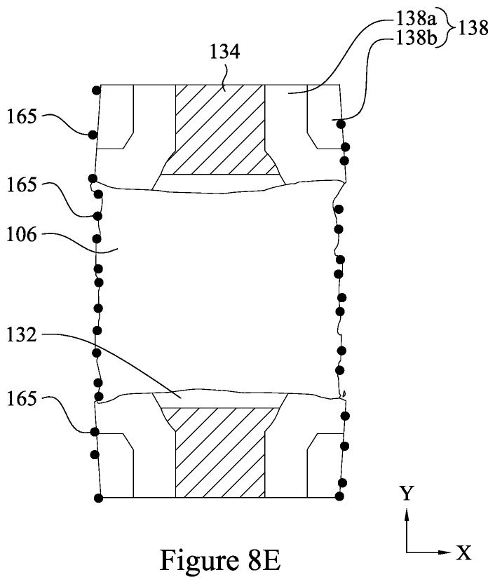

In FIGS. 8A-8D, edge portions of each second semiconductor layer 108 of the stack of semiconductor layers 104 are removed horizontally along the X direction. The removal of the edge portions of the second semiconductor layers 108 forms cavities 131. In some embodiments, the portions of the second semiconductor layers 108 are removed by a selective etching process, such as an isotropic dry etch process. Since the residues and/or by-products are removed from the exposed surfaces of the stack of semiconductor layers 104 by the pre-treatment process 175-1, the etch rate loading of the second semiconductor layers 108 from top-to-bottom are substantially equal, resulting in uniform critical dimension (CD) of the second semiconductor layers 108 at different heights. In cases where the second semiconductor layers 108 are made of SiGe and the first semiconductor layers 106 are made of silicon, the second semiconductor layer 108 may be selectively and isotropically etched using a fluorine-containing etchant, such as fluorine (F₂), nitrogen trifluoride (NF₃), carbon tetrafluoride (CF₄), sulfur hexafluoride (SF₆), difluoromethane (CH₂F₂), trifluoromethane (CHF₃), and/or hexafluoroethane (C₂F₆), and hydrogen fluoride (HF). Alternatively, a selective wet etch process may be used to remove the second semiconductor layers 108. In such cases, a wet etchant, such as ammonium hydroxide (NH₄OH), tetramethylammonium hydroxide (TMAH), ethylenediamine pyrocatechol (EDP), or potassium hydroxide (KOH) solutions, may be used.

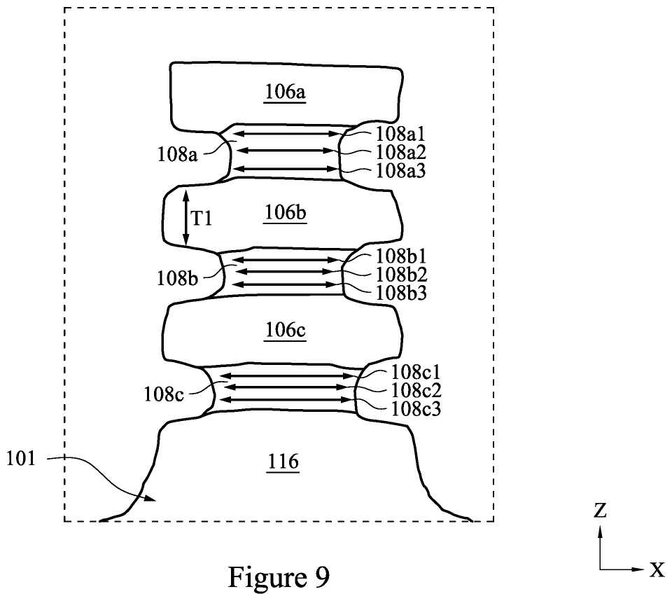

As can be seen in FIG. 8D, the sidewall 108s of the second semiconductor layers 108 has improved surface roughness due to the removal of the surface impurities (e.g., O/C/N signals) by the pre-treatment process 175-1. In some embodiments, which can be combined with any other embodiments of the present disclosure, the second semiconductor layer 108 has a smooth and substantially flat sidewall 108s along either Y-direction or Z-direction. It has been observed that the line width variation (sometimes referred to as line width roughness (LWR)) along the sidewall 108s can be improved if residues such as carbon and/or GeOₓ were previously removed by the pre-treatment process 175-1. In some embodiments, the LWR on the sidewall 108s after the pre-treatment process 175-1 is about less than 5 nm, for example about 3 nm or less. The improved LWR can lead to uniform CD of the metal gate for better device performance. In addition, the footing at the corner regions “A”, “B”, “C”, “D” of the second semiconductor layer 108 (e.g., the junction of the second semiconductor layer 108, the gate spacer 138, and the sacrificial gate dielectric layer 132) is removed to form a sharper angle to nearly vertical, as will be discussed in more detail below with respect to FIG. 9.

FIG. 8E illustrates a top view of the semiconductor device structure 100 taken along cross-section E-E of FIG. 6, in accordance with some embodiments. In some embodiments, which can be combined with one or more embodiments of the present disclosure, some radical species 165 may remain on the treated surfaces of the stack of semiconductor layers 104 (e.g., first semiconductor layers 106) as well as the gate spacers 138 after removal of the edge portions of the second semiconductor layers 108, as shown in FIGS. 8D and 8E. The gate spacers 138 may have a first concentration of radical species, and the first semiconductor layers 106 may have a second concentration of radical species. In some embodiments, the first and second concentration of radical species may be substantially the same. In some embodiments, the first concentration of radical species may be greater than the second concentration of radical species.

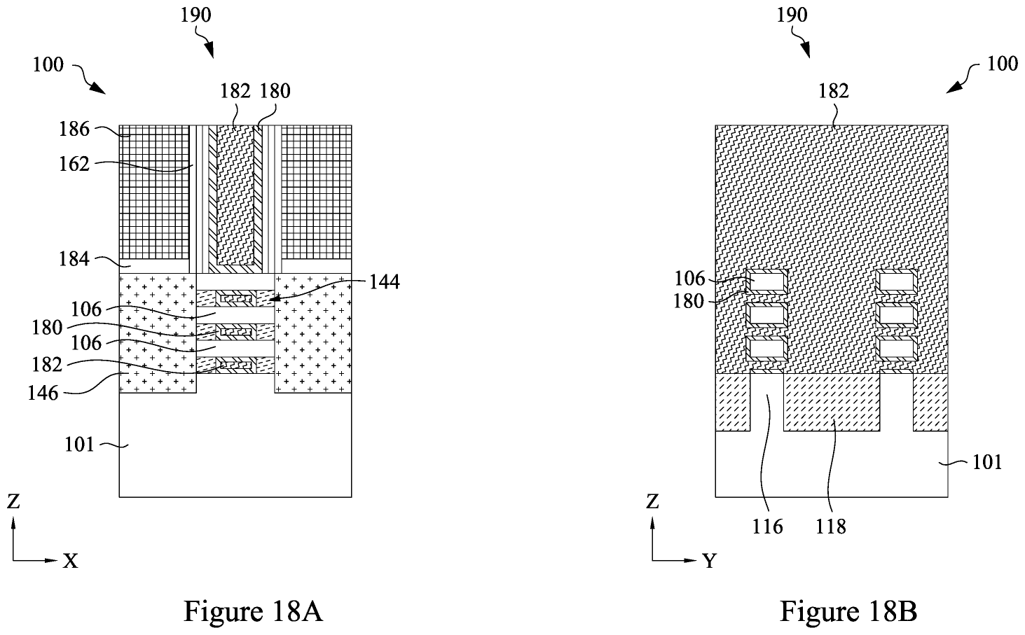

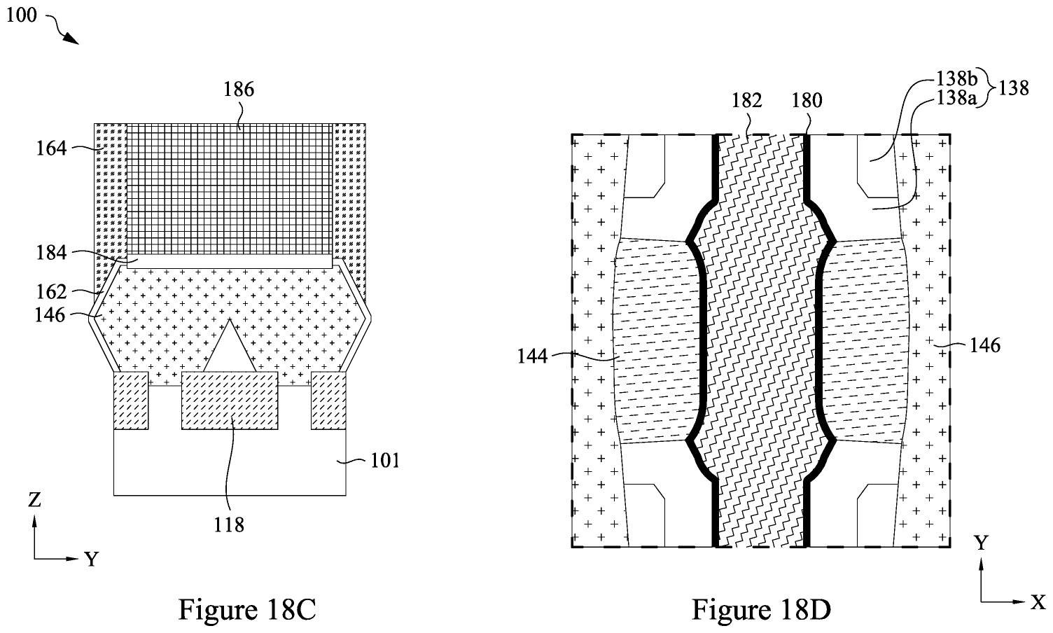

In some embodiments, the exposed surface of the first semiconductor layers 106 may be roughened because portions of the first semiconductor layers 106 may be concurrently removed during the pre-treatment process 175-1. Since some exposed surface of the first semiconductor layers 106 may not be covered by the residues 168, they will be removed at a faster etch rate than that of the first semiconductor layers 106 covered by the residues 168. As a result, the exposed surface of the first semiconductor layers 106 may be formed with surface roughness, and the exposed surfaces of the gate spacer 138 and/or the first semiconductor layers 106 may have radical species embedded thereon, as shown in FIG. 8E. While not shown, it is contemplated that the first semiconductor layers 106 may carry such a roughened or irregular surface profile and traceable amount of radical species at a later stage, such as after the replacement gate is formed (e.g., FIG. 18A).

FIG. 9 illustrates a portion of the semiconductor device structure 100 of FIG. 8A, in accordance with some embodiments. The second semiconductor layer 108a between the first semiconductor layers 106a and 106b has a uniform critical dimension (CD) in which an upper portion 108a1 has a first CD, a middle portion 108a2 has a second CD substantially equal to the first CD, and a lower portion 108a3 has a third CD substantially equal to the second CD. In some embodiments, which can be combined with any other embodiments of the present disclosure, the first CD, the second CD, and the third CD are slightly different from each other. For example, the first and third CDs may be substantially the same, which is greater than the second CD. In one example, the difference between the first CD, the second CD, and the third CD is less than 3 nm.

Likewise, the second semiconductor layer 108b between the first semiconductor layers 106b and 106c has a uniform critical dimension (CD) in which an upper portion 108b1 has a fourth CD, a middle portion 108b2 has a fifth CD substantially equal to the fourth CD, and a lower portion 108b3 has a sixth CD substantially equal to the fifth CD. In some embodiments, which can be combined with any other embodiments of the present disclosure, the fourth CD, the fifth CD, and the sixth CD are slightly different from each other. For example, the fourth and sixth CDs may be substantially the same, which is greater than the fifth CD. In one example, the difference between the fourth CD, the fifth CD, and the sixth CD is less than 3 nm.

Similarly, the second semiconductor layer 108c between the first semiconductor layer 106c and the well portion 116 of the substrate 101 has a uniform critical dimension (CD) in which an upper portion 108c1 has a seventh CD, a middle portion 108c2 has an eighth CD substantially equal to the seventh CD, and a lower portion 108c3 has a ninth CD substantially equal to the eighth CD. In some embodiments, which can be combined with any other embodiments of the present disclosure, the seventh CD, the eighth CD, and the ninth CD are slightly different from each other. For example, the seventh and ninth CDs may be substantially the same, which is greater than the eighth CD. In one example, the difference between the seventh CD, the eighth CD, and the ninth CD is less than 3 nm.

In some embodiments, which can be combined with any other embodiments of the present disclosure, the first, second, and third first semiconductor layers 106a, 106b, 106c have a thickness T1 in a range of about 3 nm to about 6 nm.

In some embodiments, the first, second, third, fourth, fifth, sixth, seventh, eighth, and ninth CDs at a first device region have a first dimensional feature, and the first, second, third, fourth, fifth, sixth, seventh, eighth, and ninth CDs at a second device region have a second dimensional feature that is different from the first dimensional feature.

In some embodiments, which can be combined with any other embodiments of the present disclosure, each of the first, second, and third CDs have a first width W1, each of the fourth, fifth, and sixth CDs have a second width W2 substantially equal to the first width W1, and each of seventh, eighth, and ninth CDs have a third width W3 substantially equal to the second width W2. In some examples, the first width W1, the second width W2, and the third width W3 may be in a range of about 12 nm to about 18 nm.

In some embodiments, which can be combined with any other embodiments of the present disclosure, each of the first, second, and third CDs have a first width W1, each of the fourth, fifth, and sixth CDs have a second width W2 substantially equal to the first width W1, and each of seventh, eighth, and ninth CDs have a third width W3 greater than the second width W2.

In some embodiments, which can be combined with any other embodiments of the present disclosure, the first, second, and third CDs have a first width W1, each of the fourth, fifth, and sixth CDs have a second width W2 greater than the first width W1, and each of seventh, eighth, and ninth CDs have a third width W3 greater than the second width W2, partially due to the high aspect ratio of the structure.

In some embodiments, each of the first width W1, the second width W2, the third width W3 at a first device region have a first dimensional feature, and each of the first width W1, the second width W2, the third width W3 at a second device region have a second dimensional feature that is different than the first dimensional feature.

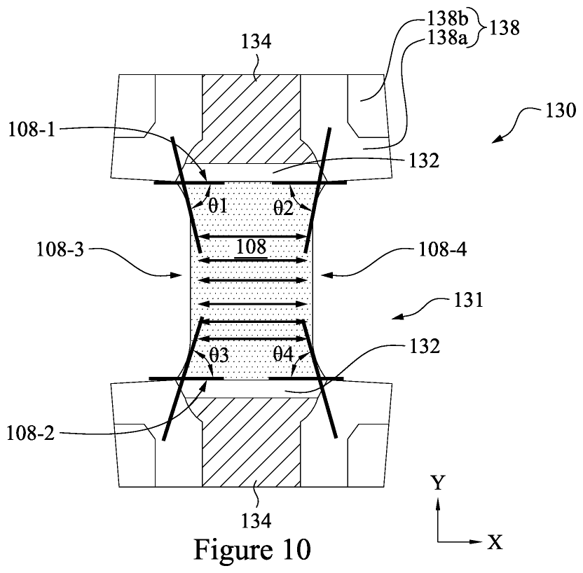

FIG. 10 illustrates a portion of the semiconductor device structure 100 of FIG. 8D after edge portions of each second semiconductor layer 108 of the stack of semiconductor layers 104 are removed, in accordance with some embodiments. While not shown, the exposed surfaces of the gate spacers 138 may have radical species 165 from the pre-treatment process 175-1, as shown in FIG. 8D. In one embodiment, the second semiconductor layer 108 has a first sidewall 108-1 disposed against the sacrificial gate dielectric layer 132 on a first side of the sacrificial gate structure 130, a second sidewall 108-2 opposing the first sidewall 108-1 and disposed against the sacrificial gate dielectric layer 132 on a second side of the sacrificial gate structure 130, a third sidewall 108-3 connecting the first sidewall 108-1 to the second sidewall 108-2, and a fourth sidewall 108-4 opposing the third sidewall 108-3 and connecting the first sidewall 108-1 to the second sidewall 108-2.

In some embodiments, the first sidewall 108-1 and the third sidewall 108-3 form an angle θ1 in a range of about 45 degrees to about 90 degrees. The first sidewall 108-1 and the fourth sidewall 108-4 form an angle θ2 in a range of about 45 degrees to about 90 degrees. The second sidewall 108-2 and the third sidewall 108-3 form an angle θ3 in a range of about 45 degrees to about 90 degrees. The second sidewall 108-2 and the fourth sidewall 108-4 form an angle θ4 in a range of about 45 degrees to about 90 degrees.

In some embodiments, which can be combined with any other embodiments of the present disclosure, the angle θ1, the angle θ2, the angle θ3, and the angle θ4 are substantially the same. In one example, the angle θ1, the angle θ2, the angle θ3, and the angle θ4 are about 50 degrees to about 70 degrees, for example about 60 degrees.

In some embodiments, which can be combined with any other embodiments of the present disclosure, the angle θ1 and the angle θ2 are substantially the same, and the angle θ3, and the angle θ4 are substantially the same, wherein the angle θ1 is different than the angle θ3. For example, the angle θ1 is greater than the angle θ3. Alternatively, the angle θ1 is less than the angle θ3.

In some embodiments, which can be combined with any other embodiments of the present disclosure, the angle θ1 and the angle θ3 are substantially the same, and the angle θ2, and the angle θ4 are substantially the same, wherein the angle θ1 is different than the angle θ2. For example, the angle θ1 is greater than the angle θ2. Alternatively, the angle θ1 is less than the angle θ2.

In any of the embodiments shown in FIG. 10, the second semiconductor layer 108 has a flat or smooth roughness along the Y-direction (e.g., longitudinal direction) and uniform critical dimension (CD) on the third sidewall 108-3 and the fourth sidewall 108-4.

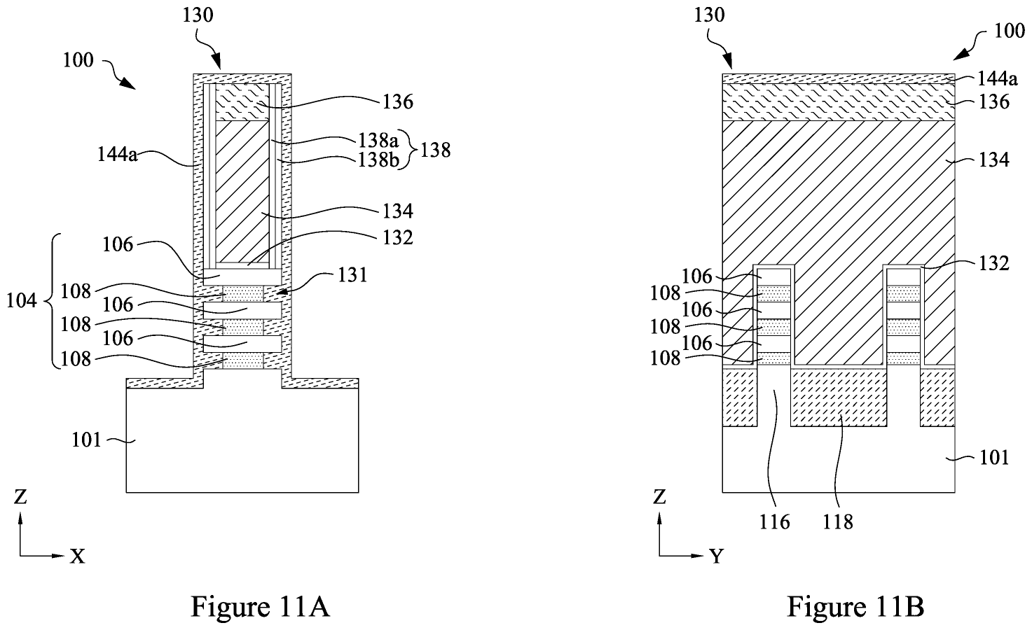

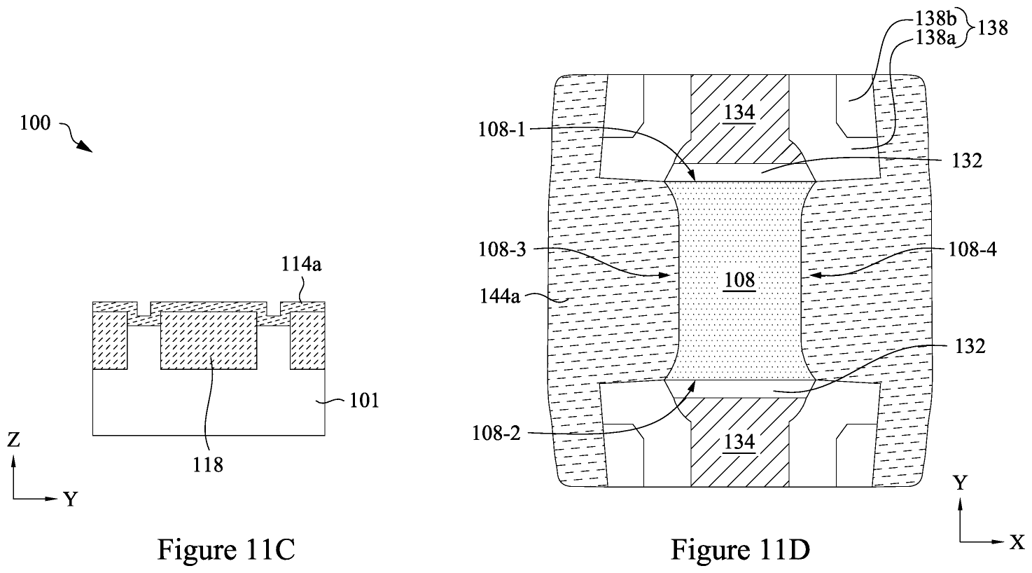

In FIGS. 11A-11D, a dielectric layer 144a is deposited on the exposed surfaces of the semiconductor device structure 100. The dielectric layer 144a also fills the cavities 131 (FIG. 8A) formed as a result of removal of the edge portions of the second semiconductor layers 108. The dielectric layer 144a is in contact with the treated surfaces of the second semiconductor layers 108 exposed through the cavities 131. Suitable materials for the dielectric layer 144a may include, but are not limited to, SiO₂, Si₃N₄, SiC, SiCP, SiON, SiOC, SiCN, SiOCN, and/or other suitable material. Other materials, such as low-k materials with a k value less than about 3.5, may also be used. The formation of the dielectric layer 144a may be formed by a conformal deposition process, such as ALD. In some embodiments, the dielectric layer 144a is a single layer structure. In some embodiments, the dielectric layer 144a is a multi-layer structure including two or more of the materials discussed herein.

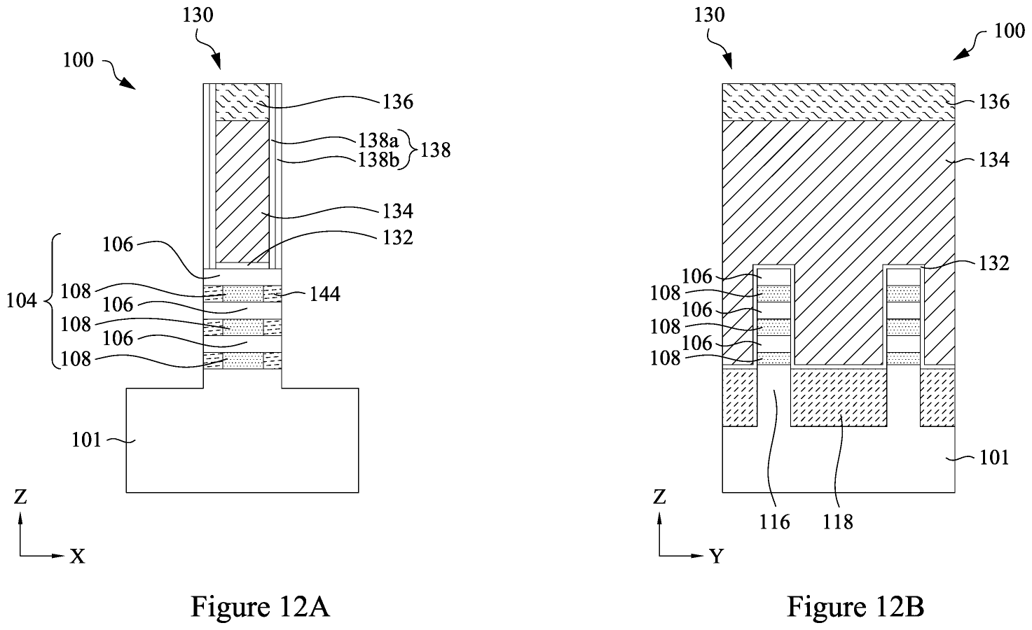

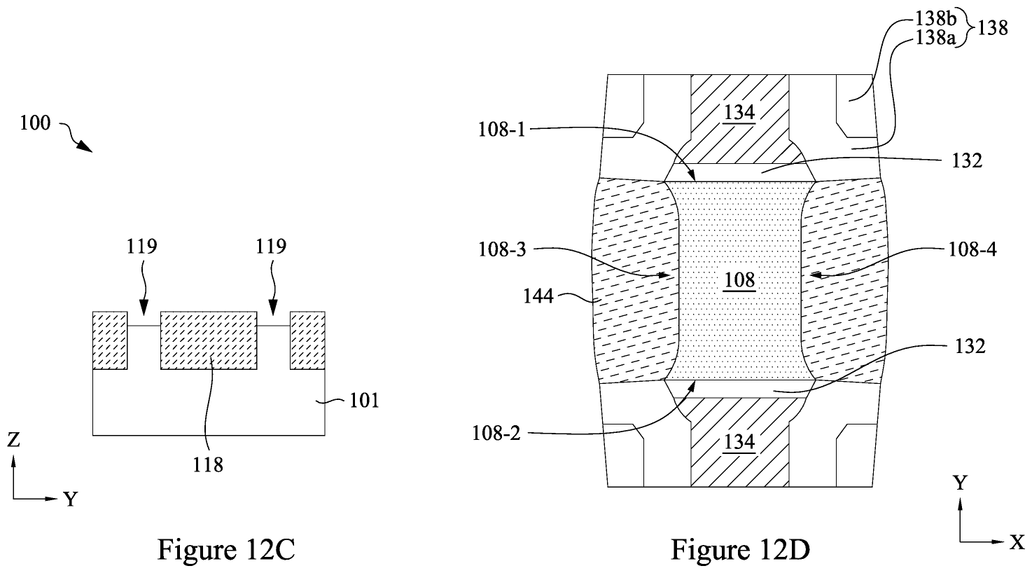

In FIGS. 12A-12D, an etch process is performed such that only portions of the dielectric layer 144a remain in the cavities 131 (FIG. 8A) and form dielectric spacers 144. The removal process may be any suitable etch processes, such as dry etch, wet etch, or a combination thereof. The etch process may be a selective etch process using an etchant that selectively removes the dielectric layer 144a without substantially removing the sacrificial gate structures 130 and the first semiconductor layers 106. The removal of the portions of the dielectric layer 144a may be performed by an anisotropic etching. The dielectric layer 144a within the cavities 131 are protected by the first semiconductor layers 106 during the anisotropic etching process. The remaining second semiconductor layers 108 are capped between the dielectric spacers 144 along the X direction.

In FIGS. 13A-13D, epitaxial S/D features 146 are formed in the source/drain (S/D) regions. The epitaxial S/D features 146 may grow laterally from the first semiconductor layers 106. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The second semiconductor layer 108 under the sacrificial gate structure 130 are separated from the epitaxial S/D features 146 by the dielectric spacers 144. The epitaxial S/D features 146 may grow both vertically and horizontally to form facets, which may correspond to crystalline planes of the material used for the first semiconductor layers 106. In some cases, the epitaxial S/D features 146 of a fin structure may grow and merge with the epitaxial S/D features 146 of the neighboring fin structures, as one example shown in FIG. 13C.

The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

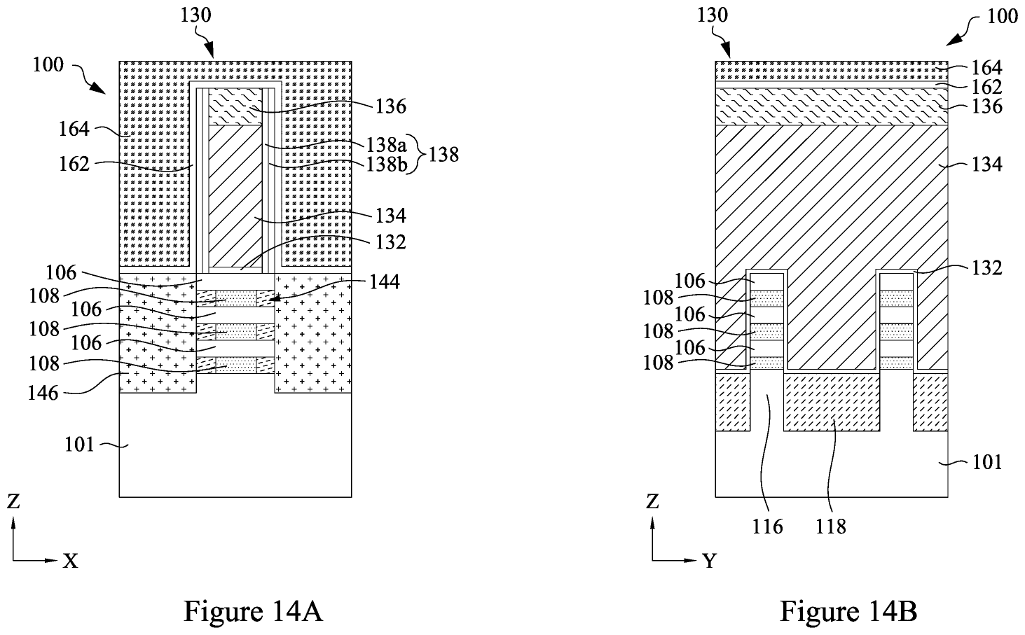

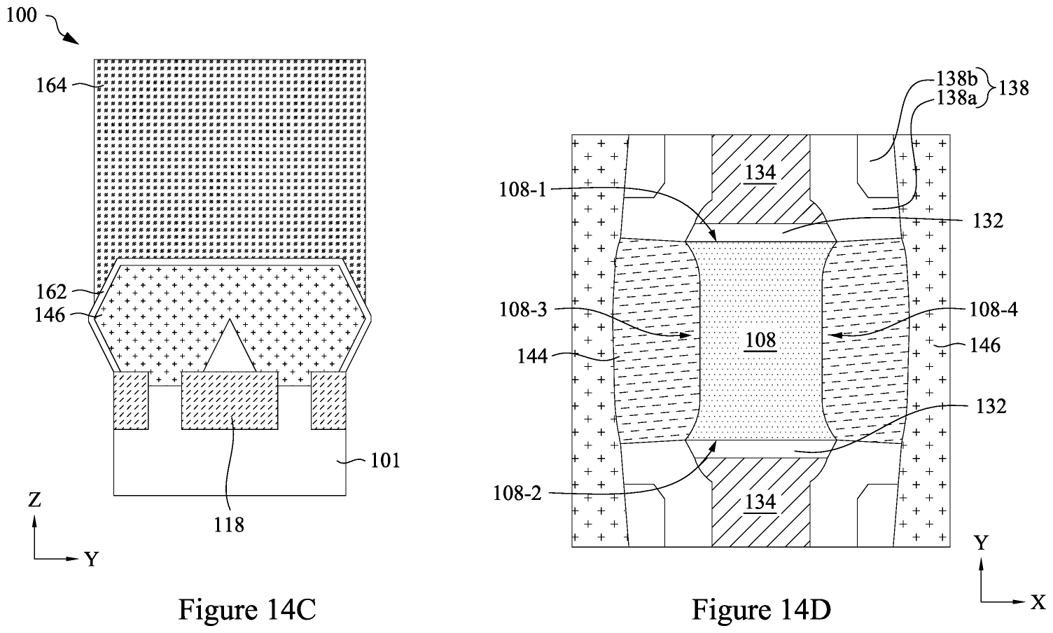

In FIGS. 14A-14D, a contact etch stop layer (CESL) 162 is conformally formed on the exposed surfaces of the semiconductor device structure 100. The CESL 162 covers the top surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

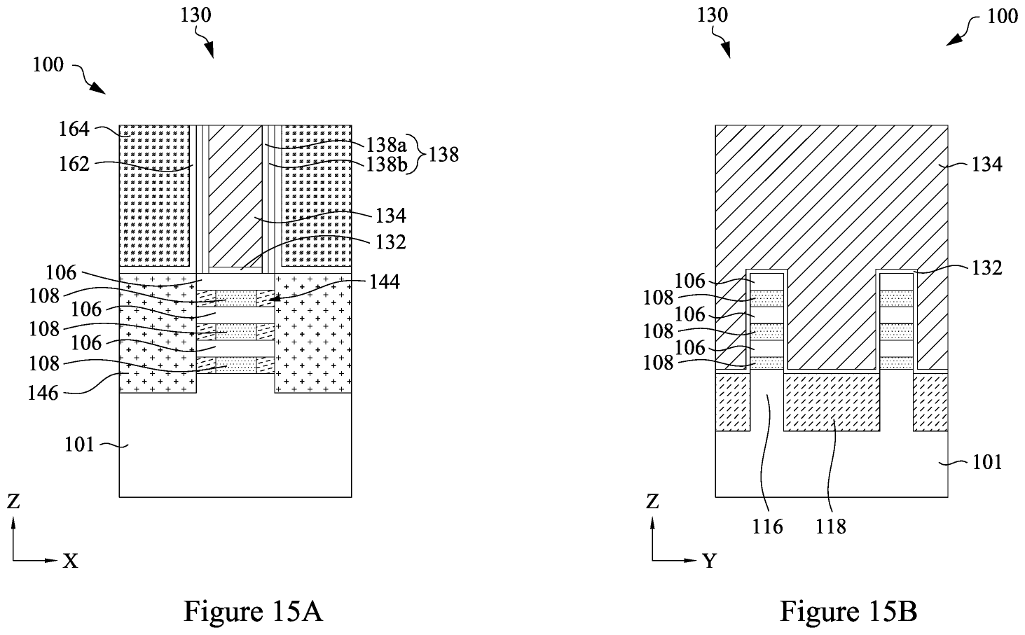

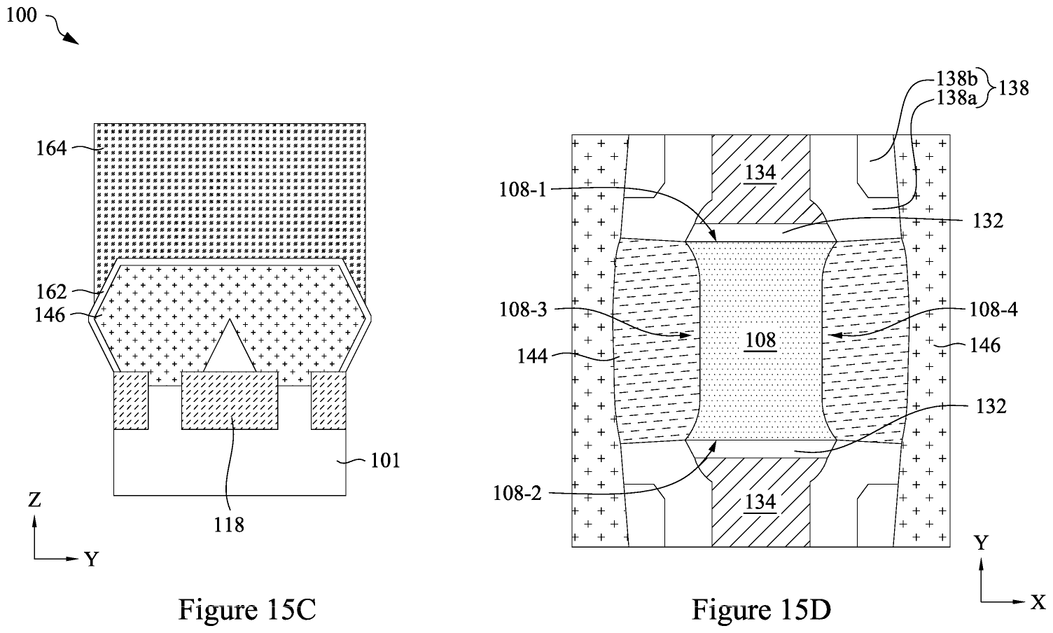

In FIGS. 15A-15D, after the first ILD layer 164 is formed, a planarization operation, such as CMP, is performed on the semiconductor device structure 100 until the sacrificial gate electrode layer 134 is exposed.

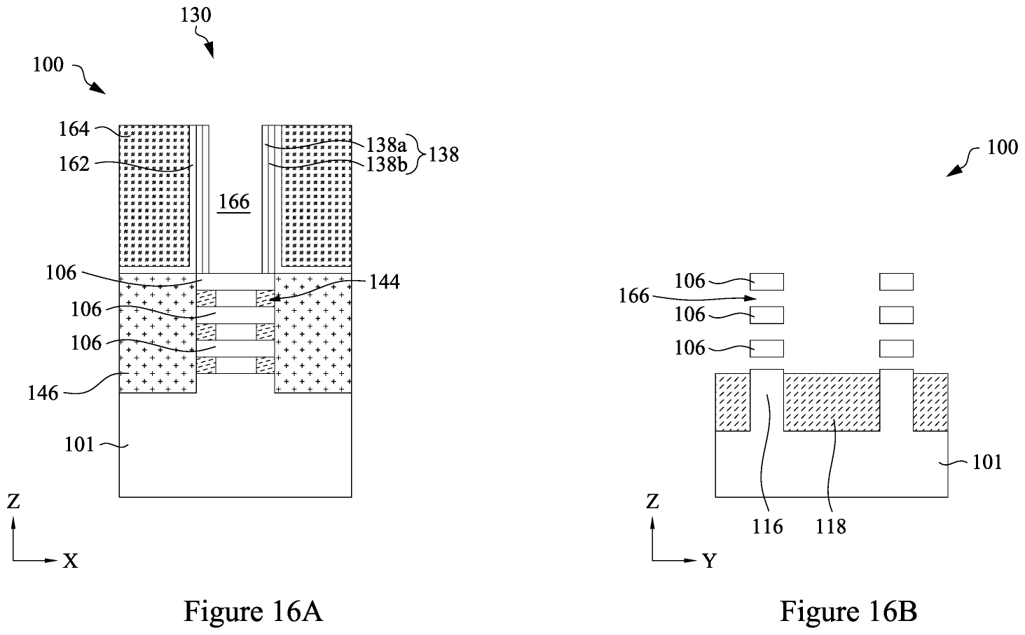

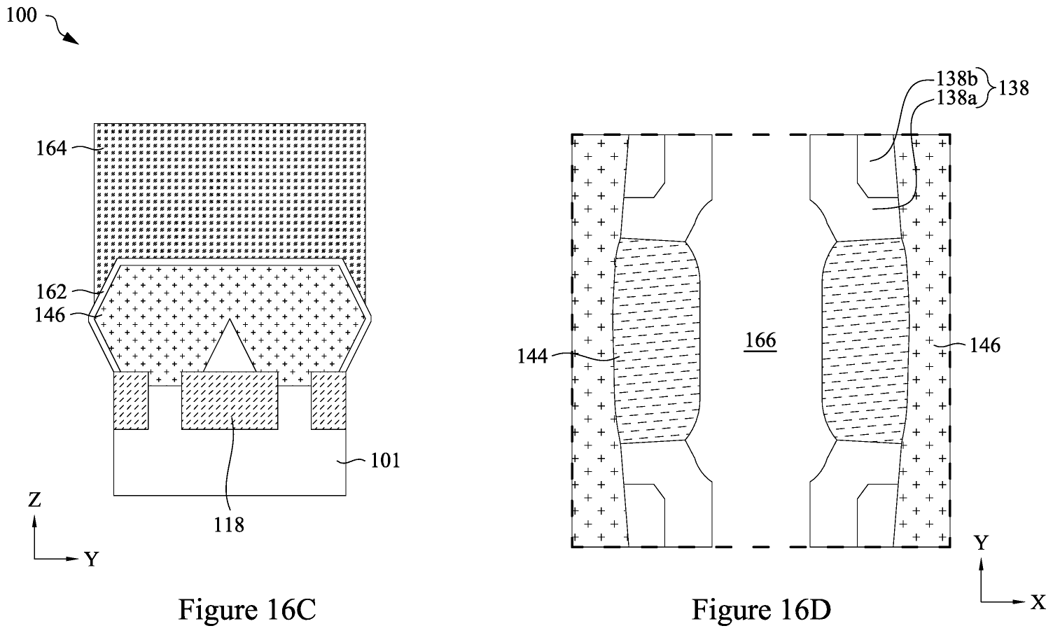

In FIGS. 16A-16D, the sacrificial gate structure 130 and the second semiconductor layers 108 are sequentially removed. The removal of the sacrificial gate structure 130 and the semiconductor layers 108 forms an opening 166 between gate spacers 138 and between adjacent first semiconductor layers 106. The first ILD layer 164 protects the epitaxial S/D features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the first ILD layer 164, and the CESL 162.

The removal of the sacrificial gate structure 130 exposes the first semiconductor layers 106 and the second semiconductor layers 108. An etch process, which may be any suitable etch processes, such as dry etch, wet etch, or a combination thereof, is then performed to remove the second semiconductor layers 108. The etch process may be a selective etch process that removes the second semiconductor layers 108 but not the gate spacers 138, the first ILD layer 164, the CESL 162, and the first semiconductor layers 106. In cases where the second semiconductor layers 108 are made of SiGe or Ge and the first semiconductor layers 106 are made of Si, the chemistry used in the selective wet etching process removes the SiGe while not substantially affecting Si, the dielectric materials of the gate spacers 138, the dielectric spacers 144, the first ILD layer 164, and the CESL 162. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants. Upon completion of the etch process, a portion of the first semiconductor layers 106 not covered by the dielectric spacers 144 is exposed to the opening 166.

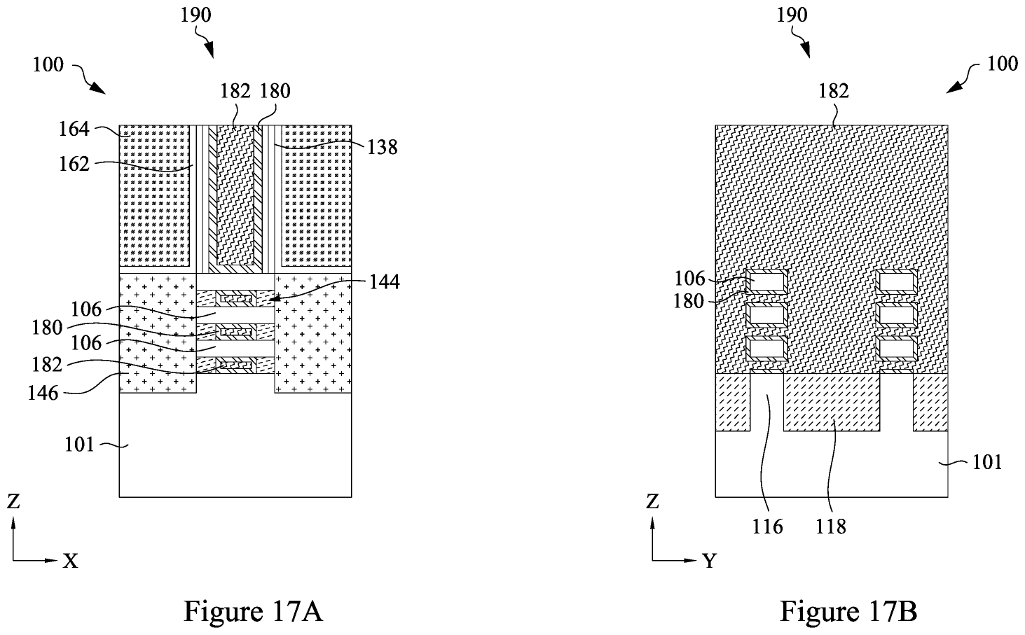

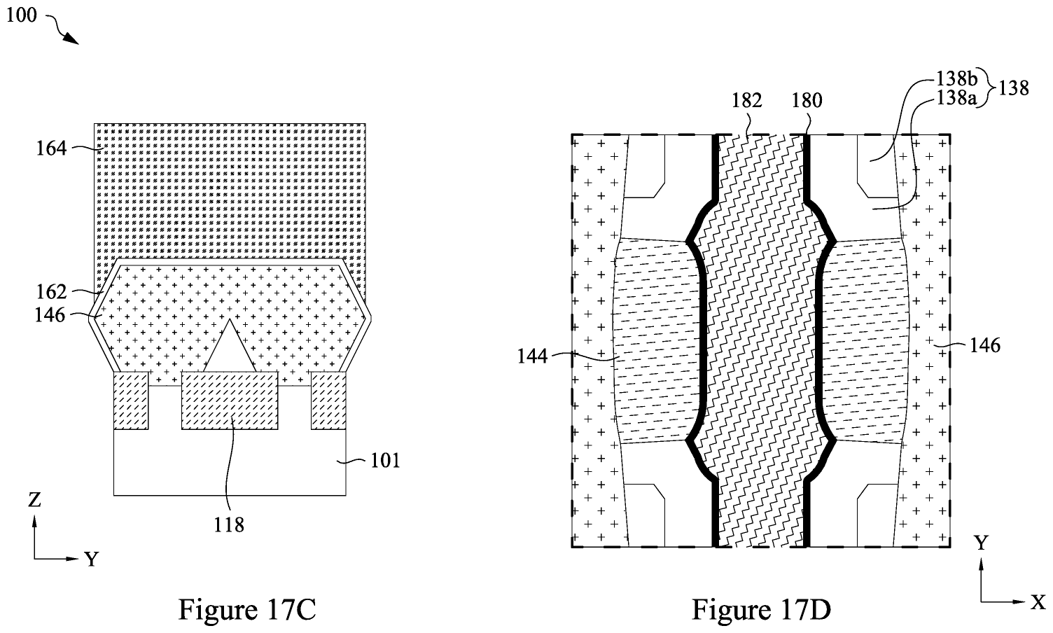

In FIGS. 17A-17D, replacement gate structures 190 are formed. The replacement gate structures 190 may each include a gate dielectric layer 180 and a gate electrode layer 182. In some embodiments, an interfacial layer (IL) (not shown) may be formed between the gate dielectric layer 180 and the first semiconductor layer 106. The IL may also form on the exposed surfaces of the substrate 101. The IL may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, and the CESL 162). The gate dielectric layer 180 may be formed of a material chemically different than that of the sacrificial gate dielectric layer 132. The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The gate dielectric layer 180 may be a conformal layer formed by a conformal process, such as an ALD process, a PECVD process, a molecular-beam deposition (MBD) process, or the like, or a combination thereof.

After formation of the IL (if any) and the gate dielectric layer 180, the gate electrode layer 182 is formed on the gate dielectric layer 180. The gate electrode layer 182 filles the openings 166 (FIG. 16A) and surrounds a portion of each of the first semiconductor layers 106. Due to implementation of the pre-treatment process 175-1 prior to formation of the dielectric spacers 144, the critical dimension (CD) variation and surface roughness of the SiGe layers are reduced. As a result, the required uniform CD control of gate electrode layer 182 is obtained. As can be seen in FIG. 17D, the gate electrode layer 182 has a uniform CD along the Y-direction.

The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, and the gate spacers 138 may be removed by a planarization process, such as by a CMP process. After the CMP process, the top surfaces of the first ILD layer 164, the CESL 162, the gate spacers 138, and the gate electrode layer 182 are substantially co-planar.

In FIGS. 18A-18D, contact openings are formed through the first ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. While not shown, a barrier layer (e.g., TiN, TaN, or the like) may be formed on sidewalls of the contact openings prior to forming the S/D contacts 186.

After the formation of the contact openings, a silicide layer 184 is formed on the epitaxial S/D features 146. The silicide layer 184 conductively couples the epitaxial S/D features 146 to subsequent S/D contacts 186 formed in the contact openings. The silicide layer 184 may be formed by depositing a metal source layer over the epitaxial S/D features 146 and performing a rapid thermal annealing process. During the rapid anneal process, the portion of the metal source layer over the epitaxial S/D features 146 reacts with silicon in the epitaxial S/D features 146 to form the silicide layer 184. Unreacted portion of the metal source layer is then removed. The silicide layer 184 may include a metal or metal alloy silicide, and the metal includes a noble metal, a refractory metal, a rare earth metal, alloys thereof, or combinations thereof. Next, a conductive material is formed in the contact openings and form the S/D contacts 186. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Various embodiments or examples described herein offer multiple advantages over the state-of-art technology. According to embodiments of the present disclosure, a pre-treatment process using neutral radical of species (e.g., N* and H*) is performed prior to formation of dielectric spacer 144, thereby removing residues from exposed surfaces of SiGe layers 108 that are disposed alternatingly stacked with nanostructure channel layers 106. The pre-treatment process improves top-to-bottom etch loading of SiGe layers 108 during subsequent removal of SiGe layers 108, thereby enabling uniform deposition of the inner spacers while reducing CD variation and surface roughness of the SiGe layers 108. As a result, the sacrificial gate dielectric layer and the inner spacers are prevented from being damaged, thereby maintaining CD control of metal gate and the integrality of the epitaxial source/drain features during the subsequent gate placement process.

An embodiment is a method for forming a semiconductor device structure. The method includes forming a sacrificial gate structure over a portion of a fin structure comprising a plurality of first semiconductor layers and a plurality of second semiconductor layers alternatingly stacked. The method also includes removing a portion of the fin structure not covered by the sacrificial gate structure, subjecting exposed surfaces of each first and second semiconductor layers to at least one radical species, removing an edge portion of the second semiconductor layers to form a cavity between two adjacent first semiconductor layers, and forming a dielectric spacer in the cavity.

Another embodiment is a method for forming a semiconductor device structure. The method includes removing a portion of first and second semiconductor layers alternatingly stacked, wherein at least two surfaces of each second semiconductor layer is disposed between a gate spacer and a sacrificial gate electrode layer, respectively. The method also includes treating exposed surfaces of each first and second semiconductor layers with first radical species and second radical species, selectively removing edge portion of each second semiconductor layer such that each second semiconductor layer has a substantially flat surface along a longitudinal direction of the second semiconductor layer, depositing a dielectric spacer between two adjacent first semiconductor layers, wherein the dielectric spacer is in contact with the second semiconductor layer. The method further includes forming epitaxial source/drain features so that a portion of the epitaxial source/drain features is in contact with the first semiconductor layer and the dielectric spacer.

A further embodiment is a method for forming a semiconductor device structure. The method includes providing a fin structure comprising a plurality of first semiconductor layers and a plurality of second semiconductor layers alternatingly stacked, forming a sacrificial gate structure and a gate spacer over a portion of the fin structure, removing a portion of the fin structure not covered by the sacrificial gate structure by an etch process, wherein the exposed surfaces of the first and second semiconductor layers are covered by etch residues from at least the gate spacer. The method also includes removing the etch residues by reacting the first radical species and the second radical species with the etch residues, and selectively removing a portion of the second semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a sacrificial gate structure over a portion of a fin structure comprising a plurality of first semiconductor layers and a plurality of second semiconductor layers alternatingly stacked;
removing a portion of the fin structure not covered by the sacrificial gate structure;
subjecting exposed surfaces of each first and second semiconductor layers to at least one radical species;
removing an edge portion of the second semiconductor layers to form a cavity between two adjacent first semiconductor layers; and
forming a dielectric spacer in the cavity.

2. The method of claim 1, wherein the at least one radical species is formed from a nitrogen-containing gas and a hydrogen-containing gas.

3. The method of claim 2, wherein each first and second semiconductor layers are exposed to neutral radical species of nitrogen and the hydrogen.

4. The method of claim 2, wherein the at least one radical species are generated by a remote plasma generator disposed in an upstream of a reaction chamber.

5. The method of claim 1, wherein the at least one radical species are directed to remove by-products generated during removal of the portion of the fin structure.

6. The method of claim 5, wherein the by-products comprise native oxides on the exposed surfaces of each first and second semiconductor layers and a gate spacer of the sacrificial gate structure.

7. The method of claim 1, further comprising:
after subjecting exposed surfaces of each first and second semiconductor layers to the at least one radical species, subjecting the exposed surfaces of each first and second semiconductor layers to a surface cleaning process using hydrofluoric acid (HF) and/or diluted HF.

8. A method for forming a semiconductor device structure, comprising:
removing a portion of first and second semiconductor layers alternatingly stacked, wherein at least two surfaces of each second semiconductor layer is disposed between a gate spacer and a sacrificial gate electrode layer, respectively;
treating exposed surfaces of each first and second semiconductor layers with first radical species and second radical species;
selectively removing edge portion of each second semiconductor layer such that each second semiconductor layer has a substantially flat surface along a longitudinal direction of the second semiconductor layer;
depositing a dielectric spacer between two adjacent first semiconductor layers, wherein the dielectric spacer is in contact with the second semiconductor layer; and
forming epitaxial source/drain features so that a portion of the epitaxial source/drain features is in contact with the first semiconductor layer and the dielectric spacer.

9. The method of claim 8, wherein the first and second radical species are directed to remove by-products generated during removal of the gate spacer.

10. The method of claim 9, wherein the by-products comprise silicon oxycarbide.

11. The method of claim 8, wherein a sidewall surface exposed as a result of removal of the edge portion of each second semiconductor layer has a substantially uniform critical dimension (CD) along the longitudinal direction of the second semiconductor layer.

12. The method of claim 11, wherein the CD is about 3 nm or less.

13. The method of claim 8, wherein the first radical species include atomic radicals of nitrogen, and the second radical species include atomic radicals of hydrogen.

14. The method of claim 13, wherein each first and second semiconductor layers are exposed to the first radical species and the second radical species provided at a ratio of about 6:1 to about 25:1.

15. The method of claim 8, further comprising:
prior to selectively removing edge portion of each second semiconductor layer, subjecting the treated surfaces of first and second semiconductor layers to a pre-clean process using HF or diluted HF.

16. The method of claim 14, further comprising:
after forming epitaxial source/drain features, removing the sacrificial gate electrode layer and the second semiconductor layers.

17. A method for forming a semiconductor device structure, comprising:
providing a fin structure comprising a plurality of first semiconductor layers and a plurality of second semiconductor layers alternatingly stacked;
forming a sacrificial gate structure and a gate spacer over a portion of the fin structure;
removing a portion of the fin structure not covered by the sacrificial gate structure by an etch process, wherein the exposed surfaces of the first and second semiconductor layers are covered by etch residues from at least the gate spacer;
removing the etch residues by reacting the first radical species and the second radical species with the etch residues; and
selectively removing a portion of the second semiconductor layers.

18. The method of claim 17, wherein the first semiconductor layers have a first concentration of first and second radical species after removal of the etch residues, and the first semiconductor layers have a second concentration of first and second radical species after selective removal of the portion of the second semiconductor layers, and wherein the first concentration of first and second radical species is greater than the second concentration of first and second radical species.

19. The method of claim 18, wherein the first radical species include atomic radicals of nitrogen, and the second radical species include atomic radicals of hydrogen.

20. The method of claim 17, wherein the exposed surfaces of the first semiconductor layers have roughened surface profile.
